(19) United States
(12) Patent Application Publication
(10) Pub. No.: US 2008/0042145 A1
(43) Pub. Date: Feb. 21, 2008

(54) DIFFUSION BARRIER FOR LIGHT EMITTING DIODES

(76) Inventors: Helmut Hagleitner, Zebulon, NC (US); Zoltan Ring, Durham, NC (US); Jason Gurganus, Raleigh, NC (US)

Correspondence Address: SUMMA, ALLAN & ADDITON, P.A., 11610 NORTH COMMUNITY HOUSE ROAD, SUITE 200, CHARLOTTE, NC, 28277, US

(21) Appl. No.: 11/465,497

(22) Filed: Aug. 18, 2006

(51) Int. Cl. H01L 33/00

(52) U.S. Cl. 257/79

(57) ABSTRACT

A structure is disclosed for preventing reflector metals from migrating in light emitting diodes. The structure includes respective p-type and n-type semiconductor epitaxial layers for generating recombinations and photons under an applied current, a reflecting metal layer proximate at least one of the epitaxial layers for increasing the light output in a desired direction, a first layer of titanium tungsten on the reflecting metal layer, a layer of titanium tungsten nitride on the first titanium tungsten layer, and a second layer of titanium tungsten on the tungsten titanium nitride layer opposite from the first titanium tungsten layer.

### BACKGROUND

The present invention relates to light emitting diodes, and in particular relates to light emitting diodes formed from Group III nitride materials on silicon carbide substrates.

A light emitting diode is a photonic device that emits light when current passes across the p-n junction that forms the diode. As a partial list, light emitting diodes are widely used as status indicators (on/off lights) on professional and consumer electronic audio and video equipment, seven segment displays (e.g. calculators), light weight message displays in public information signs, alphanumeric displays in environments where night vision must be retained, remote controls for televisions and related equipment (using infrared LEDs), fiber optic communications, traffic signals, and car brake lights and turn signals. LEDs are also appearing more frequently as illumination sources such as flashlights and back lighting for liquid crystal display (LCD) video screens, and as replacements for incandescent and fluorescent bulbs in home and office lighting.

In accordance with well-understood principles of physics, the color(s) of the light emitted by the diode is fundamentally determined by the bandgap of the semiconductor material from which the diode is formed. Because the frequency of light is directly related to energy, semiconductor materials with larger bandgaps emit higher energy, higher frequency photons. Because the Group III nitrides have bandgaps of at least about 3.37 electron volts (eV), they can be used to form diodes that emit light at shorter wavelengths (e.g. below 500 nanometers(nm)) which fall into the green, blue and violet portions of the visible spectrum and into portions of the ultraviolet spectrum. In contrast, the lower bandgaps of materials such as silicon (1.11 eV), gallium arsenide (1.43 eV), and indium phosphide (1.34 eV) produce photons of lower energy in the longer-wavelength red and yellow portions of the visible spectrum.

The capacity of Group III nitrides to emit blue light provides the corresponding advantage of obtaining white light from solid state sources; i.e. combinations of blue, green and red LEDs. Alternatively, blue or UV-emitting LEDs can also be used to excite selected phosphors that in turn produce a white emission or an emission (e.g. yellow) that combines with the LED's blue emission to produce white light.

The Group III nitrides also have the advantage of being “direct” emitters, meaning that the energy emitted by a transition between the conduction band and the valence band is primarily generated as light (a photon) rather than as vibration (phonon) and resulting heat.

For a number of reasons, Group III nitride based devices are often formed of epitaxial layers of the desired Group III materials on a substrate formed of a different material. In some cases the material is sapphire (Al₂O₃) which offers an acceptable crystal match, chemical stability, and physical strength. Sapphire can also be formed in transparent fashion so as to avoid interfering with the extraction of light from the diode.

Sapphire, however, cannot be conductively doped and thus diodes formed on sapphire must have a “horizontal” orientation; i.e., the ohmic contacts to the p-side and n-side of the diode must generally face in the same direction. This tends to increase the overall area (“footprint”) of the diode.

Accordingly, in many applications silicon carbide (SiC) provides a better alternative as a substrate for Group III nitride light emitting diodes. Silicon carbide is physically strong and chemically robust (inert to attack) and can be formed in transparent or near-transparent crystals. As an additional advantage, silicon carbide can be conductively doped and thus permits diodes to be formed in “vertical” orientation; i.e. with the ohmic contacts on opposite ends (taken axially) of the device. This permits the footprint of a silicon carbide based diode to be smaller than the footprint of a sapphire based diode based on the same area for the junction and the Group III nitride layers.

The basic elements of a light emitting diode typically include (but are not limited to) one p-type layer of semiconductor material and an adjacent n-type layer of semiconductor material that together form a p-n junction. These layers are structurally supported by an appropriate substrate and are also in electrical contact with respective ohmic metals. Accordingly, when current is injected through the ohmic contacts and across the p-n junction, at least some of the resulting electronic transitions produce photons, and at least some of the photons escape from the diode in the form of visible light.

In some light emitting diodes, the semiconductor portions of the device are mounted in a “flip-chip” orientation. In use, this places the structural substrate on the emitting side of the device and the p-n junction toward the mounting structure. The mounting structure often includes a reflective layer. When light is emitted from the junction that otherwise would be absorbed by the mounting structure, the reflective layer re-directs the light back towards the output side of the device.

Regardless of the particular LED structure, the reflective layer serves a useful purpose because the recombination-generated photons are emitted from the active structure in all directions. The usual goal is, however, to direct light in a particular direction, and to maximize the visible output. Thus, the presence of a reflector layer (often referred to as a mirror) can both increase the light emitted in a particular direction and increase the total visible output of the LED.

Silver (Ag) is a useful metal (perhaps the most useful) for such reflective purposes along with other metals such as gold (Au) and aluminum (Al). As a disadvantage, however, silver tends to migrate between and among adjacent layers of metal and semiconductors. When silver migrates in this fashion, it can affect the electrical and chemical properties of the device and reduce, degrade, or destroy its functional LED properties. For example, the manufacture of flip-chip LEDs typically includes at least one soldering step, such as soldering the chip to a lead frame (also referred to as a “slug,” or “die pad”). This step, among others, can require heating the solder, lead frame and chip to temperatures on the order of 350° C. As is often the case in chemical reactions, this higher temperature encourages the undesired migration of the reflector metal.

As a result, structures that incorporate reflective layers of silver and similar metals must typically include some structure that moderates or prevents the silver from migrating into undesired portions of the device. To date, relatively complex multilayer structures have been used, as well as layers that include relatively expensive metals such as platinum (Pt). For example, commonly assigned and copending application Ser. No. 10/951,042 filed Sep. 22, 2004 for High Efficiency Group III Nitride-Silicon Carbide Light Emitting Diode discloses a layer of tin (Sn) for preventing silver from migrating as well as more complex layers such as titanium, tungsten or platinum, their alloys, and multiple layers of such metals, their alloys or combinations of these materials.

### SUMMARY

In one aspect, the invention is a structure for preventing reflector metals from migrating in light emitting diodes. The structure includes respective p-type and n-type semiconductor epitaxial layers for generating recombinations and photons under an applied current, a reflecting metal layer proximate at least one of the epitaxial layers for increasing the light output in a desired direction, a first layer of titanium tungsten on the reflecting metal layer, a layer of titanium tungsten nitride on the first titanium tungsten layer, and a second layer of titanium tungsten on the tungsten titanium nitride layer opposite from the first titanium tungsten layer.

In another aspect, the invention is a method of preventing reflector metals within light emitting diode structures from migrating into or reacting with other elements in the light emitting diode. The method includes the steps of depositing a first layer of titanium tungsten onto a layer of a reflector metal that is part of a light emitting active structure that includes semiconductor epitaxial layers and at a deposition temperature that is below the temperature that would otherwise interfere with the structure or function of the light emitting active structure, depositing a layer of titanium tungsten nitride on said first titanium tungsten layer at a temperature below the temperature that would otherwise interfere with the structure or function of the light emitting active structure, and depositing a second layer of titanium tungsten on the titanium tungsten nitride layer at a temperature below the temperature that would otherwise interfere with the structure or function of the light emitting active structure.

In another aspect the invention is a light emitting diode (LED) that includes a lead frame, an active structure in electrical contact with the lead frame, a reflecting metal layer between the lead frame and the active structure for directing emitted light away from the lead frame, a barrier structure for preventing the metal in the reflecting layer from migrating within the light emitting diode, the barrier structure comprising a first layer of titanium tungsten covering the reflecting metal layer, a layer of titanium tungsten nitride covering the first titanium tungsten layer, and a second layer of titanium tungsten covering the titanium tungsten nitride layer, and an ohmic contact in electrical communication with the active structure opposite from the lead frame.

The foregoing and other objects and advantages of the invention and the manner in which the same are accomplished will become clearer based on the followed detailed description taken in conjunction with the accompanying drawings.

### BRIEF DESCRIPTION OF THE DRAWINGS

FIG. 1 is a cross sectional schematic illustration of certain features of the present invention.

FIG. 2 is a cross-sectional schematic illustration of a light emitting diode that incorporates features according to the present invention.

FIG. 3 is a photograph of semiconductor wafers formed according to the method of the invention.

### DETAILED DESCRIPTION

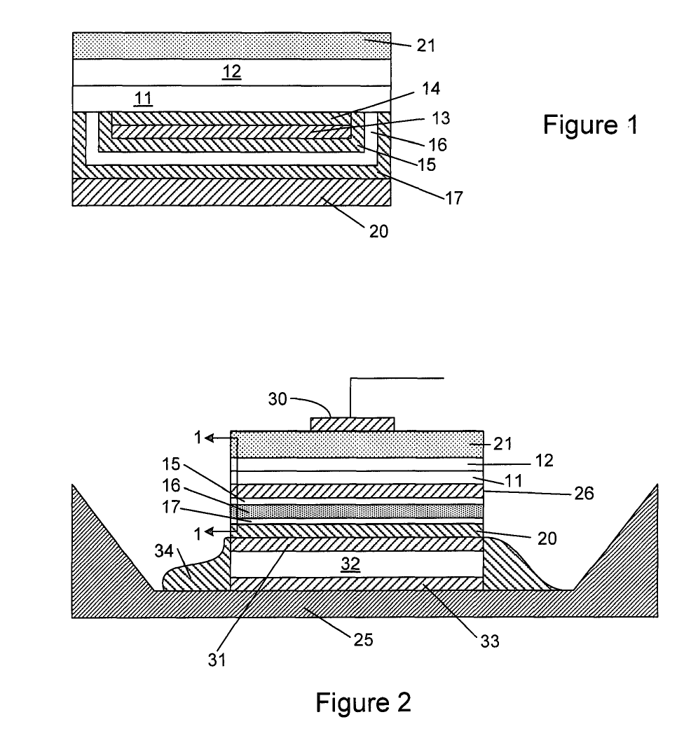

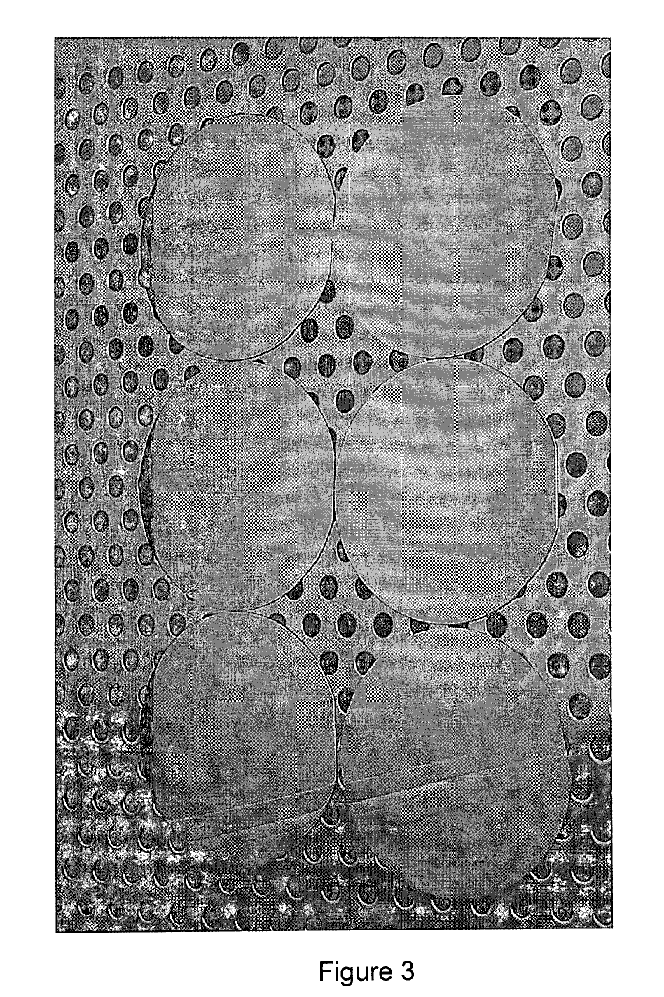

FIG. 1 is a schematic cross sectional view of the basic structure of the invention in the form of a diode precursor broadly designated at 10. The illustrated structure prevents reflector metals from migrating in light emitting diodes. The structure includes respective p-type 11 and n-type 12 semiconductor epitaxial layers for generating recombinations and photons under an applied current across the p-n junction. A reflecting metal layer 13, typically (but not exclusively) formed of silver is proximate at least one of the epitaxial layers 11 or 12 for increasing the light output in a desired direction. FIG. 1 illustrates the reflecting metal layer 13 as closest to the p-type epitaxial layer 11, but this is a function of the flip-chip orientation described herein rather than any limitation of the invention.

FIG. 1 also illustrates an electrical contact layer 14, typically but not necessarily formed of platinum, between the reflecting metal layer 13 and the epitaxial layer I 1. Because the reflecting metal layer 13 has the primary purpose of optically reflecting photons, it may be less suitable than some other metals for making electrical contact with a semiconductor material in the epitaxial layers. Other metals are less reflective, but more suitable for electrical contact to the epitaxial layers. Thus, the metal contact layer 14 can be included to enhance the electrical contact properties even though it may not serve as well as a reflector as does (for example) silver. The metal contact layer 13 is thin enough, however, to substantially avoid interfering with the reflecting function of the reflecting metal layer 13.

In order to prevent the silver from migrating, the structure includes a first layer 15 of titanium tungsten (TiW) alloy on the reflecting metal layer 13. A layer of titanium tungsten nitride (TiWN) 16 is on the first titanium tungsten layer 15, and a second layer of titanium tungsten 17 is on the titanium tungsten nitride layer opposite from the first titanium tungsten layer 15. As illustrated in FIG. 1, the first titanium tungsten layer 15 covers substantially the entire reflecting metal layer 13 other than the surface of the reflecting metal layer 13 that faces the active structure (epitaxial layers 11 and 12).

Although the schematic illustration of FIG. 1 does not include every possible element of a light emitting diode, it does include a solder layer 20 and a silicon carbide substrate 21. As set forth in the Background, the silicon carbide substrate 21 is illustrated in upper portions of the diode 10 because of the flip chip orientation, while the solder layer 20 is used to mount the diode for various purposes during both manufacture and end use. The respective positions of the reflecting metal layer 13 and the silicon carbide substrate 21 increases the light output towards, and thus through, the substrate 21.

Even though FIGS. 1 and 2 both illustrate substrates in the flip-chip orientation, other LED structures (including Group III nitride based devices) can include a more conventional orientation in which the emitting surface is formed of one of the active layers, or of a highly doped Group III nitride layer that encourages current spreading. The invention is also compatible with such structures.

The titanium tungsten nitride layer 16 provides a favorable barrier against migration of the reflecting metal layer 13. The adhesion properties of the titanium tungsten nitride layer 16 are less favorable, however, than the adhesion properties (to adjacent layers) of titanium tungsten and thus the titanium tungsten layers 15, 17 provide an additional structural advantage as well as forming part of the overall barrier.

The reflecting metal layer 13 is typically silver, but can be selected from any other appropriately reflecting metal, example of which include gold, silver, aluminum, and combinations of these metals.

The barrier layers 15, 16 and 17 have a total thickness that is sufficient to prevent migration or diffusion of the reflecting metal from the reflecting metal layer 13 into the remainder of the diode 10, but less a thickness at which the resulting stress would encourage delamination and related structural problems in the titanium-containing layers 15, 16, and 17. Those familiar with the growth of epitaxial layers of semiconductors and related thin materials will recognize that the barrier layers only need to be thick enough to accomplish the intended purpose. Once the barrier is thick enough to prevent migration, increasing the layer thickness may tend to increase the physical stress within each layer without any added benefit as a barrier.

Generally, successful barriers have been formed with the titanium tungsten layers 15, 17 each being about 1000 angstroms (Å) thick and the titanium tungsten nitride layer being about 2000 Å thick.

In exemplary embodiments, the semiconductor epitaxial layers 11 and 12 are Group III nitrides. Group III nitrides include those compounds of gallium, aluminum, indium and nitrogen that form binary, ternary, and quaternary compounds. The selection of any one or more of these layers for homojunctions, heterojunctions, single or multiple quantum wells, or superlattice structures, is a matter of choice when used in conjunction with the present invention. Thus the present invention can incorporate any number of such compounds or layers. In some embodiments, the epitaxial layers are gallium nitride (GaN), while in others they are aluminum gallium nitride (AlGaN) or indium gallium nitride (InGaN).

Those of skill in the art recognize that these formulas are more precisely expressed as AlₓGa₁₋ₓN or InₓGa₁₋ₓN. In particular, because the band gap of InₓGa₁₋ₓN changes based upon the mole fraction of indium in the compound, InGaN diodes can be produced with output at a desired wavelength by correspondingly selecting the proper mole fraction of indium.

FIG. 2 is another schematic diagram of a light emitting diode according to the invention. As between FIG. 1 and FIG. 2, FIG. 1 corresponds generally (although not exactly) to a view along lines 1-1 of FIG. 2. In particular, FIG. 1 shows slightly more detail about the reflecting layer 13 and metal contact layer 14 than does FIG. 2. Otherwise, like elements carry like reference numerals.

In FIG. 2, a light emitting diode is broadly designated at 24. The diode 24 includes a lead frame 25 and an active structure in electrical contact with the lead frame. In FIG. 2 as in FIG. 1, the active structure is illustrated as, but not limited to, the semiconductor epitaxial layers 11 and 12. As with respect to FIG. 1, the active structure can also include a heterostructure, a double heterostructure, a quantum well, a multiple quantum well, or a superlattice structure. Accordingly, FIG. 2 will be understood as illustrative rather than limiting of the invention.

FIG. 2 illustrates the reflecting metal layer at 26 as a single layer. A barrier structure 27 prevents the metal in the reflecting layer 26 from migrating within the light emitting diode 24. The barrier structure again includes the first layer of titanium tungsten 15 covering the reflecting metal layer 26, a layer of titanium tungsten nitride 16 covering the first titanium tungsten layer 15, and a second layer of titanium tungsten 17 covering the titanium tungsten nitride layer 16. An ohmic contact 30 is in electrical connection with the active structure opposite from the lead frame 25.

As in FIG. 1, in exemplary embodiments of the diode 24 the epitaxial layers 11 and 12 are formed of Group III nitrides. Based upon the flip chip orientation and method of manufacture, the diode 24 includes the transparent silicon carbide substrate 21 between the active layer structure 11, 12 and the ohmic contact 30.

As in the previously described embodiment, the reflecting metal layer 26 is most typically selected from the group consisting of gold, silver, aluminum, and combinations thereof. Although not illustrated, because of the relative size of FIG. 2 the diode 24 will typically include the electrical contact layer that is illustrated as 14 in FIG. 1.

The diode 24 corresponds in its general structure to the XBRIGHT® series of diodes available from Cree, Inc., the assignee herein. Because these diodes are in the flip chip orientation, their method of manufacture and resulting structure often include a submount structure which FIG. 2 illustrates as another solder layer 31, a second substrate 32, and a second ohmic contact 33. The exact structure and composition of the submount structure need not correspond to these three illustrated layers, but will function in the same manner to provide a supporting structure for the diode's active portions and to provide electrical contact to the lead frame 25. Thus, the second substrate 32 is often formed of silicon carbide but can also be formed of other appropriate materials potential including metals.

FIG. 2 also illustrates that the active layers 11 and 12 and a number of other elements of the diode 24 are held to the lead frame using an appropriate solder 34.

In partial summary, the invention is a layer of titanium tungsten nitride sputter-deposited as a compound between two layers of titanium tungsten alloy. This prevents diffusion of metal or moisture through the layers. The titanium tungsten nitride compound acts as a barrier and prevents metals such as gold, silver, aluminum from diffusing, even during or after heat treatment. As a result, this barrier can replace more elaborate or expensive barriers such as platinum in current barrier layers resulting in large cost savings. Although the bordering layers of titanium tungsten do not by themselves form the barrier to silver migration, they do provide adhesion layers for incorporating the barrier more easily and functionally into device designs.

The invention also includes the method of forming the light emitting diode structure. In particular, the method comprises a first step of depositing a layer of titanium tungsten on the diode precursor structure (i.e.; including the active structure described herein in terms of the epitaxial layers 11 and 12) at a temperature below the temperature that would otherwise interfere with the structure or function of the light emitting diode.

A second step comprises depositing a layer of titanium tungsten nitride on the first titanium tungsten layer and again at a temperature below the temperature that would otherwise interfere with the structure or function of the light emitting diode. A third step comprises depositing a second layer of titanium tungsten on the titanium tungsten nitride layer and again carrying out the depositing step at a temperature below the temperature that would otherwise interfere with the structure or function of the light emitting diode.

In exemplary embodiments, the TiW and TiWN layers are deposited by sputtering. The nature, concept and specific steps of sputter deposition are well understood in this art and will not be described in detail. In general, a relatively high voltage is applied across a low pressure gas, such as argon (Ar) at about 5 milliTorr, to create a plasma. During sputtering, the energized plasma atoms strike a target composed of the desired coating material and cause atoms from that target to be ejected with enough energy to travel to, and bond with, the desired substrate.

Currently, and in the method of the invention, a favored sputtering technique uses pulsed direct current (DC) power. The use of pulsed DC power (as opposed to continuous DC power or RF power) for thin-film deposition in semiconductor manufacturing is generally well understood in this art. Helpful discussions can be found in numerous sources including, Belkin et al., Single-Megatron Approach Reactive Sputtering of Dielectrics, Vacuum Technology & Coating, September 2000, or from magnetron and power supply manufactures such as Advanced Energy Industries, Inc. of Fort Collins, Colo. 80525 USA (www.advanced-energy.com) or Angstrom Sciences, Inc. Duquesne Pa. 15110 USA (www.angstromsciences.com).

As described in these sources and as understood in this art, pulsed DC sputtering techniques can be carried out as cold-momentum transfer processes and thus avoid the effects of high temperature on the substrate or the coating, which high temperatures tend to be produced by other forms of sputtering. Additionally, pulsed DC sputtering can be used to apply either conductive or insulating materials to a wide variety of substrates including metals, semiconductors, ceramics, and even heat-sensitive polymers.

In further detail, the titanium tungsten nitride (TiWN) layer is produced by reactive ion sputtering using the pulsed DC technique. Reactive ion sputtering includes a deposition source material in the plasma gas. Thus, the titanium tungsten nitride layer is formed by sputtering titanium and tungsten from respective solid sources in the presence of both argon and nitrogen gas.

In particular, the respective deposition steps are carried out below the dissociation temperature of the semiconductors that form the epitaxial layers. Furthermore, the deposition steps should be carried out below temperatures that would encourage unwanted side effects such as dopant migration within the active layers, or activation of elements, states, or defects within the epitaxial layers, all of which can affect the electronic behavior of the active structure or can physically interfere with the emission of light from the resulting diode.

Because gallium nitride tends to dissociate above temperatures of about 600° C. (depending upon ambient conditions) the deposition steps should be carried out below this temperature and preferably below about 500° C.

The adjustment of the sputter deposition process to meet these requirements is generally well understood in the art. Some of the relevant parameters include the target power density, the current applied to the electromagnets in the deposition system, the flow and partial pressure of argon (and where appropriate nitrogen), the deposition temperature, and the substrate rotation. Those of skill in this art will recognize that the exact adjustment of each of these parameters can and will differ from system to system, but that the deposition can be carried out without undue experimentation.

The sputter deposition is typically carried out using a titanium tungsten alloy target and, for the titanium tungsten nitride layer, nitrogen in the argon atmosphere. The composition of the resulting coatings can be expressed as TiₓW_{y} or as TiₓW_{y}N_{z}. For the TiW layers, X is between about 0.6 and 0.7 (60 and 70 mole percent) with Y as the remainder. For titanium tungsten nitride, X is between about 0.3 and 0.45, Y is between about 0.3 and 0.4, and Z is between about 0.25 and 0.3.

The quality of the resulting layers expressed in terms of non-migration of the silver, can be identified using the following procedures.

### Experimental

The titanium tungsten nitride layers were characterized in the following manner. Two 3-inch liftoff monitors were placed in two rows on a pallet of SEGI. Two thermally oxidized 3-inch wafers were placed in two rows on the pallet of SEGI. Two double-side polished thin 3-inch silicon wafers were placed in two rows on a pallet of SEGI. The inner wafer edge of all wafers was 0.5 inches from the inner edge of the pallet. The titanium tungsten nitride alloy was sputter deposited using pulsed DC in ten experiments as indicated in Table 1. The thickness was measured from the liftoff monitor using P10. Sheet resistance was measured using a four-point probe on thermal oxide monitors. Stress was calculated from pre- and post-bow measurements on opposite sides of the film on the thin silicon wafer. Bulk resistance was calculated from thickness and sheet resistance measurements.

TABLE 1

| | | | | | | Stress | Stress |
|---|---|---|---|---|---|---|---|
| | | | Deposition | Sheet | | (Mpa) | (Mpa) |
| | Pressure | N₂ | Rate | Resistivity | Uniformity | Inner | Outer |
| Experiment | (mT) | (sccm) | (Å/min) | (μΩ-cm) | (%) | Row | Row |
| 1 | 6 | 4 | 100.7 | 181.502 | 7.045 | −832.001 | −766.9439 |
| 2 | 8 | 8 | 97.9 | 254.605 | 15.495 | −235.2911 | −349.7162 |
| 3 | 8 | 6 | 97.5 | 221.6175 | 10.255 | −743.4949 | −812.4766 |
| 4 | 10 | 4 | 96.6 | 229.695 | 7.995 | −1364.728 | −1244.705 |
| 5 | 6 | 8 | 111.8 | 220.4367 | 8.34 | −284.6722 | −402.3374 |
| 6 | 8 | 4 | 96.6 | 203.6591 | 6.775 | −1201.083 | −1116.352 |
| 7 | 10 | 8 | 93.4 | 287.4503 | 18.145 | −330.6076 | −405.7451 |
| 8 | 8 | 6 | 96.4 | 220.5251 | 10.875 | −811.4779 | −774.976 |
| 9 | 10 | 6 | 89.5 | 236.368 | 12.205 | −805.2909 | −779.5354 |
| 10 | 6 | 6 | 100.0 | 188.2784 | 6.94 | −664.5228 | −583.2757 |

Table 2 provides ellipsometer measurements used to evaluate the resulting structures. The angle measurement was taken with a Gaertner Ellipsometer (Gaertner Scientific, Skokie, Ill. 60076, USA) and proved that the TiWN layer is a solid barrier for Au/Ag diffusion. As Table 2 illustrates, Ψ and Δ remained substantially identical after heat treatment. Wafers were then put in vacuum oven at 350° C. and Au was ellipsometric spectra monitored.

TABLE 2

| | As | | 350° C.; | | 350° C.; | |
|---|---|---|---|---|---|---|
| | Deposited | | 1 Hr | | 4 Hr | |
| Experiment | Ψ | Δ | Ψ | Δ | Ψ | Δ |
| 1 | 43.14 | 109.32 | 43.24 | 109.92 | 43.18 | 109.56 |
| 2 | 43.1 | 109.28 | 43.2 | 109.67 | 43.18 | 109.52 |
| 3 | 43.15 | 109.53 | 43.22 | 109.75 | 43.22 | 109.62 |
| 4 | 43.14 | 109.61 | 43.22 | 110.13 | 43.18 | 110 |
| 5 | 43.19 | 109.22 | 43.22 | 109.87 | 43.19 | 109.66 |
| 6 | 43.19 | 109.44 | 43.22 | 110.18 | 43.17 | 110.05 |
| 7 | 43.12 | 109.19 | 43.21 | 109.72 | 43.19 | 109.57 |
| 8 | 43.13 | 109.53 | 43.13 | 109.95 | 43.16 | 109.81 |
| 9 | 43.12 | 109.39 | 43.17 | 109.88 | 43.15 | 109.72 |
| 10 | 43.14 | 109.24 | 43.18 | 109.77 | 43.16 | 109.98 |

No interaction between the TiWN and Au was observed for any of the wafers.

In the drawings and specification there has been set forth a preferred embodiment of the invention, and although specific terms have been employed, they are used in a generic and descriptive sense only and not for purposes of limitation, the scope of the invention being defined in the claims.

1. A light emitting diode comprising:
respective p-type and n-type semiconductor epitaxial layers for generating recombinations and photons under an applied current;
a reflecting metal layer proximate at least one of said epitaxial layers for increasing the light output in a desired direction;
a first layer of titanium tungsten on said reflecting metal layer;
a layer of titanium tungsten nitride on said first titanium tungsten layer; and
a second layer of titanium tungsten on said tungsten titanium nitride layer opposite from said first titanium tungsten layer.

2. A light emitting diode structure according to claim 1 wherein said reflecting metal layer is selected from the group consisting of gold, silver, aluminum, and combinations thereof.

3. A light emitting diode structure according to claim 1 wherein the total thickness of said titanium-containing layers is sufficient to prevent migration or diffusion of said reflecting metal into the remainder of said diode, but less than a thickness at which the resulting stress would encourage delamination and related structural problems in said titanium-containing layers.

4. A light emitting diode according to claim 1 wherein said first and second titanium tungsten layers are about 1000 angstroms thick and said titanium tungsten nitride layer is about 2000 angstroms thick.

5. A light emitting diode structure according to claim 1 wherein said semiconductor epitaxial layers comprise Group III nitrides.

6. A light emitting diode structure according to claim 1 further comprising a semiconductor substrate on said epitaxial layers and opposite from said reflecting metal layer so that said reflecting metal layer increases light output towards said substrate.

7. A light emitting diode structure according to claim 6 wherein said substrate comprises silicon carbide.

8. A method of preventing reflector metals in light emitting diode structures from migrating, the method comprising:
depositing a first layer of titanium tungsten onto a layer of a reflector metal that is part of a light emitting active structure that includes semiconductor epitaxial layers and at a deposition temperature that is below the temperature that would otherwise interfere with the structure or function of the light emitting active structure;
depositing a layer of titanium tungsten nitride on said first titanium tungsten layer at a temperature below the temperature that would otherwise interfere with the structure or function of the light emitting active structure; and
depositing a second layer of titanium tungsten on the titanium tungsten nitride layer at a temperature below the temperature that would otherwise interfere with the structure or function of the light emitting active structure.

9. A method according to claim 8 wherein each of the respective deposition steps are carried out below the dissociation temperature of the semiconductors that form the epitaxial layers.

10. A method according to claim 8 comprising:
depositing the respective layers onto a reflector metal that is part of a light emitting active structure that includes Group III nitride epitaxial layers; and
carrying out the respective deposition steps below the dissociation temperature of the Group III nitride compounds in the epitaxial layers.

11. A method according to claim 8 comprising carrying out the respective deposition steps at a temperature that avoids dopant migration or unwanted activation of elements, states or defects within the epitaxial layers.

12. A method according to claim 8 comprising carrying out the respective deposition steps at temperatures below 500° C.

13. A method according to claim 8 comprising depositing the first and second titanium tungsten layers by pulsed DC sputter deposition.

14. A method according to claim 8 comprising depositing the titanium tungsten nitride layer by reactive pulse DC sputtering.

15. A light emitting diode comprising:
a lead frame:
an active structure in electrical contact with said lead frame;
a reflecting metal layer between said lead frame and said active structure for directing emitted light away from said lead frame;
a barrier structure for preventing the metal in said reflecting layer from migrating within said light emitting diode, said barrier structure comprising a first layer of titanium tungsten covering said reflecting metal layer, a layer of titanium tungsten nitride covering said first titanium tungsten layer, and a second layer of titanium tungsten covering said titanium tungsten nitride layer; and
an ohmic contact in electrical communication with said active structure opposite from said lead frame.

16. A light emitting diode according to claim 15 comprising a Group III nitride active structure.

17. A light emitting diode according to claim 15 further comprising a transparent substrate between said active layer structure and said ohmic contact (flip chip orientation).

18. A light emitting diode according to claim 15 further comprising a second ohmic contact on said lead frame.

19. A light emitting diode according to claim 15 wherein said reflecting metal layer is selected from the group consisting of gold, silver, aluminum, and combinations thereof.

20. A light emitting diode according to claim 15 comprising an electrical contact layer immediately between said reflecting metal layer and said active structure for enhancing the flow of current through said diode.

21. A light emitting diode according to claim 15 wherein said electrical contact layer comprises platinum and said reflecting metal layer comprises silver.

22. A light emitting diode according to claim 15 wherein said first titanium tungsten layer covers substantially all of said reflecting metal layer other than the surface of said reflecting metal layer that faces said active structure.

23. A light emitting diode according to claim 15 further comprising a solder layer and a submount structure between said second titanium tungsten layer and said second ohmic contact.
